(19) United States
(12) Patent Application Publication
(10) Pub. No.: US 2024/0402587 A1
(43) Pub. Date: Dec. 5, 2024

(54) METHOD FOR FABRICATING MASK, AND METHOD FOR MANUFACTURING SEMICONDUCTOR DEVICE USING THE SAME

(71) Applicant: Samsung Electronics Co., Ltd., Suwon-si (KR)

(72) Inventors: Joong Un Park, Suwon-si (KR); Byung Jun Kang, Suwon-si (KR); Bong Keun Kim, Suwon-si (KR); Yong-Ah Kim, Suwon-si (KR); Hyung Joo Youn, Suwon-si (KR)

(21) Appl. No.: 18/603,634

(22) Filed: Mar. 13, 2024

(30) Foreign Application Priority Data
Jun. 2, 2023 (KR) 10-2023-0071750

(51) Int. Cl. G03F 1/36; H01L 21/027; H01L 29/06; H01L 29/423; H01L 29/775; H01L 29/788

(52) U.S. Cl. CPC G03F 1/36; H01L 21/027; H01L 29/0673; H01L 29/42392; H01L 29/775; H01L 29/788

(57) ABSTRACT

A method for fabricating a mask for manufacturing a semiconductor device is provided. The method includes generating a first target pattern including a step portion having an inner corner and an outer corner that are spaced apart in a vertical direction; generating a second target pattern from the first target pattern; performing optical proximity correction on the second target pattern to generate a final pattern; and fabricating the mask using the final pattern. Generating the second target pattern includes forming a recess extending inwardly and in a diagonal direction relative to the inner corner of the step portion; and forming a protrusion protruding outwardly and in the diagonal direction relative to the outer corner of the step portion.

### CROSS-REFERENCE TO RELATED APPLICATION

This application claims priority from Korean Patent Application No. 10-2023-0071750 filed on Jun. 2, 2023, in the Korean Intellectual Property Office, and all the benefits accruing therefrom under 35 U.S.C. 119, the disclosure of which is incorporated by reference herein in its entirety.

### FIELD

The present disclosure relates to a method for fabricating a mask, and a method for manufacturing a semiconductor device using the same.

### BACKGROUND

Generally, patterns of a semiconductor chip are formed in a photolithography process and an etch process. For example, a layout for a pattern of a semiconductor chip to be formed on a wafer may be designed. When a circuit pattern on a mask is transferred onto the wafer in a photolithography process to form a circuit pattern (hereinafter, a “transferred circuit pattern”) on the wafer, a difference may be generated between the transferred circuit pattern on the wafer and an actual design circuit pattern. This difference may be due to an optical proximity effect in the photolithography process and/or a loading effect in the etch process. A scheme for accurately transferring the circuit pattern on the mask onto the wafer may employ a process proximity correction (PPC) technique to correct the circuit pattern in consideration of deformation of the transferred circuit pattern on the wafer. The process proximity correction scheme may pre-predict and pre-analyze the optical proximity effect and the loading effect, and may correct a layout of the circuit pattern on the mask based on the analysis result. An optical proximity correction (OPC) scheme in the photolithography process is typically used as the process proximity correction scheme.

### SUMMARY

Some embodiments of the present disclosure may provide a method for fabricating a mask, based on optical proximity correction.

Some embodiments of the present disclosure may provide a method for manufacturing a semiconductor device using a mask fabricated based on optical proximity correction.

Embodiments of the present disclosure are not limited to the above-mentioned purpose. Other purposes and advantages according to the present disclosure that are not mentioned may be understood based on following description, and may be more clearly understood based on examples according to the present disclosure. Further, it will be easily understood that embodiments and advantages according to the present disclosure may be realized using means shown in the claims or combinations thereof.

According to an aspect of the present disclosure, there is provided a method for fabricating a mask for manufacturing a semiconductor device. The method includes generating a first target pattern including a step portion having an inner corner and an outer corner that are spaced apart in a vertical direction; generating a second target pattern from the first target pattern; performing optical proximity correction on the second target pattern to generate a final pattern; and fabricating the mask using the final pattern. Generating the second target pattern includes forming a recess extending inwardly and in a diagonal direction relative to the inner corner of the step portion; and forming a protrusion protruding outwardly and in the diagonal direction relative to the outer corner of the step portion.

According to an aspect of the present disclosure, there is provided a method for fabricating a mask for manufacturing a semiconductor device. The method includes generating a first target pattern; generating a second target pattern from the first target pattern; performing optical proximity correction on the second target pattern to generate a final pattern; and fabricating the mask using the final pattern. The first target pattern comprises a first edge extending in a first vertical direction; a second edge connected to one end of the first edge and extending in a first horizontal direction; and a third edge connected to another end of the first edge and extending in a second horizontal direction opposite to the first horizontal direction. The second target pattern comprises a fourth edge extending in a first diagonal direction; a fifth edge connected to the fourth edge and extending in the first horizontal direction; a sixth edge connected to the fifth edge and extending in a second vertical direction opposite to the first vertical direction; a seventh edge connected to the sixth edge and extending in a second diagonal direction opposite to the first diagonal direction; an eighth edge connected to the seventh edge and extending in the second vertical direction; a ninth edge connected to the eighth edge and extending in the first horizontal direction; and a tenth edge connected to the ninth edge and extending in the first diagonal direction.

According to an aspect of the present disclosure, there is provided a method for manufacturing a semiconductor device. The method includes fabricating a mask; and performing a photo process on a substrate using the mask. Fabricating the mask includes generating a first target pattern, wherein the first target pattern includes a step portion having an inner corner and an outer corner that are spaced apart in a vertical direction; generating a second target pattern from the first target pattern; performing optical proximity correction on the second target pattern; determining a final pattern based on the optical proximity correction; and fabricating the mask using the final pattern. Generating the second target pattern includes forming a recess extending inwardly and in a diagonal direction relative to the inner corner of the step portion; and forming a protrusion protruding outwardly and in the diagonal direction relative to the outer corner of the step portion.

### BRIEF DESCRIPTION OF THE DRAWINGS

The above and other aspects and features of the present disclosure will become more apparent by describing in detail illustrative embodiments thereof with reference to the attached drawings, in which:

FIG. 1 is a flow chart for illustrating a method for fabricating a mask according to some embodiments;

FIGS. 2, 3, 4, 5, 6, and FIG. 7 are diagrams for illustrating a method for fabricating a mask according to some embodiments;

FIG. 8 is a flow chart for illustrating a method for fabricating a mask according to some embodiments;

FIG. 9 is a block diagram showing a mask fabricating device according to some embodiments;

FIG. 10 is a flow chart for illustrating a method for manufacturing a semiconductor device in accordance with some embodiments;

FIG. 11 is a block diagram for illustrating a photolithography system for performing a method for manufacturing a semiconductor device according to some embodiments;

FIG. 12 is a diagram showing an example of a photo mask included in the photolithography system of FIG. 11;

FIG. 13 is a diagram showing printing of a circuit pattern on a substrate using the photo mask of FIG. 12; and

FIGS. 14, 15, and FIG. 16 are diagrams for illustrating a semiconductor device according to some embodiments.

### DETAILED DESCRIPTION OF EMBODIMENTS

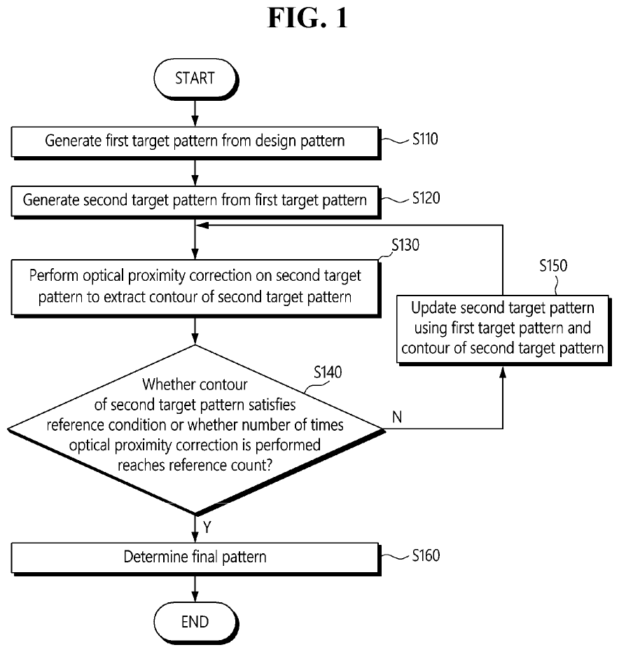

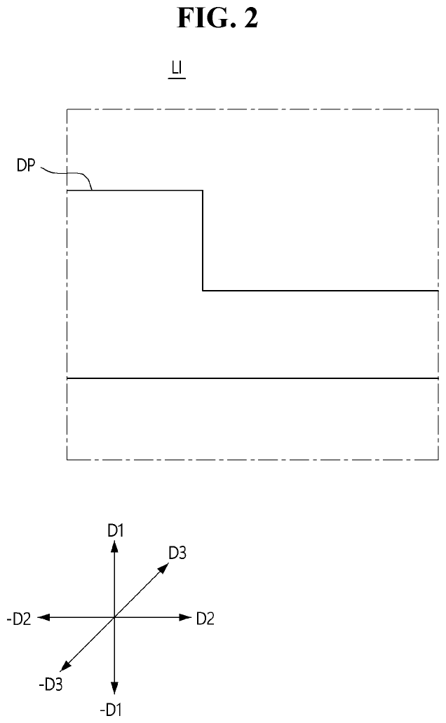

FIG. 1 is a flow chart for illustrating a method for fabricating a mask according to some embodiments. FIG. 2 to FIG. 7 are diagrams for illustrating a method for fabricating a mask according to some embodiments. The terms “comprises,” “comprising,” “includes” and/or “including,” when used herein, specify the presence of stated elements, but do not preclude the presence of additional elements. The term “and/or” includes any and all combinations of one or more of the associated listed items.

Referring to FIG. 1 and FIG. 2, an initial layout LI including a design pattern DP may be provided. The design pattern DP includes a step portion. The design pattern DP may include a portion having a first width in a first vertical direction D1 and a portion having a second width in the first vertical direction D1 smaller than the first width. The design pattern DP may have, for example, an L shape. The terms “first,” “second,” etc., may be used herein merely to distinguish one component, layer, direction, etc. from another.

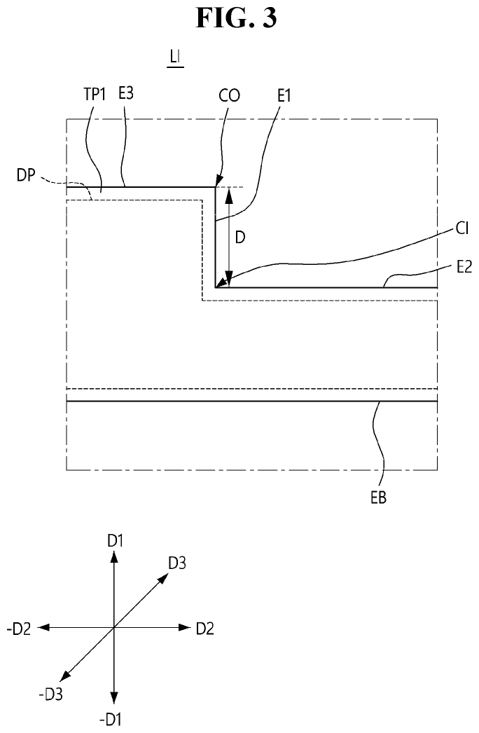

Referring to FIG. 1 and FIG. 3, a first target pattern TP1 is generated from the design pattern DP included in the initial layout LI in S110. The first target pattern TP1 may be generated from the design pattern DP in a TDLO (Table Driven Layout Operation) procedure. The first target pattern TP1 may define a size of a pattern (that is, a photoresist pattern) to be developed from a photoresist in the photolithography process, more generally referred to herein as a photo process. That is, the first target pattern TP1 may mean a target size of the photoresist pattern to be actually developed.

The design pattern DP may mean a size of a final pattern to be formed in an etch target layer under the photoresist. The final pattern formed on the etch target layer may be formed to have a smaller size than a size of the photoresist pattern formed in the photolithography process. This is because an etch profile is inclined while patterning the etch target layer using the photoresist pattern as an etch mask. In summary, generating the first target pattern TP1 in S110 is a process of correcting a difference between the size of the pattern developed from the photoresist and the size of the pattern formed in the etch target layer.

The first target pattern TP1 has a different size from that of the design pattern DP, but may have a similar shape to a shape of the design pattern DP. The first target pattern TP1 may include a step portion. The step portion includes an inner corner CI and an outer corner CO. The outer corner CO may be adjacent to the inner corner CI in the first vertical direction D1.

The first target pattern TP1 may include at least one edge extending in vertical directions D1 and −D1 and at least one edge extending in horizontal directions D2 and −D2.

Specifically, the first target pattern TP1 may include a first edge E1, a second edge E2, a third edge E3 (which may define an upper boundary of the first target pattern TP1), and a bottom edge EB (which may define a lower boundary of the first target pattern TP1). The first edge E1 may extend in the first vertical direction D1. The second edge E2 may be connected to a first end of the first edge E1 and may extend in the first horizontal direction D2. The third edge E3 may be connected to a second end of the first edge E1 and extend in the second horizontal direction −D2 opposite to the first horizontal direction D2. The inner corner CI may be defined by the first edge E1 and the second edge E2 connected to each other, that is, at a vertex defined by the ends thereof. The outer corner CO may be defined by the first edge E1 and the third edge E3 connected to each other, that is, at a vertex defined by the ends thereof. The bottom edge EB may not be connected to the inner corner CI and the outer corner CO and may extend in the horizontal directions D2 and −D2. The bottom edge EB may not include a step. Alternatively, the bottom edge EB may be composed of an edge extending in the horizontal directions D2 and −D2 and an edge extending in the vertical directions D1 and −D1, and thus include a step.

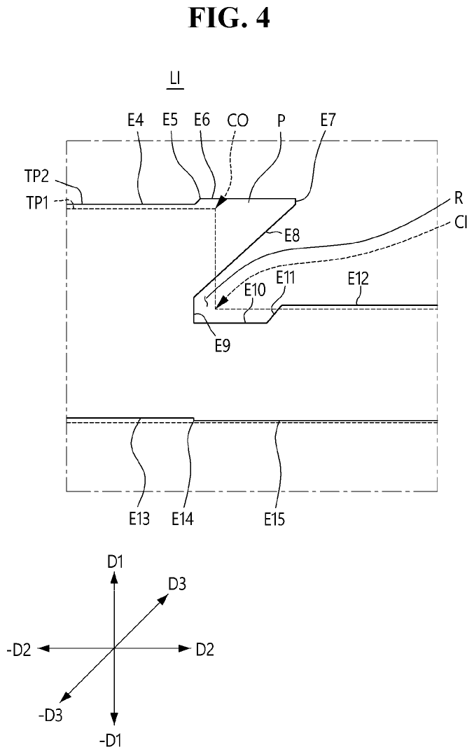

Referring to FIG. 1 and FIG. 4, a second target pattern TP2 is generated from the first target pattern TP1 in S120. The second target pattern TP2 includes a recess R and a protrusion P. The recess R extends inwardly from or relative to the inner corner CI (so as to be within the upper boundary) of the first target pattern TP1 in a second diagonal direction −D3. The protrusion P protrudes outwardly from or relative to the outer corner CO (so as to be outside the upper boundary) of the first target pattern TP1 in a first diagonal direction D3. The recess R and the protrusion P are connected to each other. The second target pattern TP2 may be formed by forming the recess R and the protrusion P from the step portion of the first target pattern TP1.

The second target pattern TP2 may include at least one edge extending in the vertical directions D1 and −D1, at least one edge extending in the horizontal directions D2 and −D2, and at least one edge extending in the diagonal directions D3 and −D3. Each of the diagonal directions D3 and −D3 may be a direction between each of the vertical directions D1 and −D1 and each of the horizontal directions D2 and −D2. An angle between each of the diagonal directions D3 and −D3 and each of the vertical directions D1 and −D1 may be 45 degrees or other non-orthogonal angle.

The second target pattern TP2 may include fourth to fifteenth edges E4 to E15. The fourth to twelfth edges E4 to E12 are sequentially connected to each other. The fourth edge E4 extends in the first horizontal direction D2. The fifth edge E5 is connected to an end of the fourth edge E4 and extends from the end of the fourth edge E4 in the first diagonal direction D3. The sixth edge E6 is connected to an end of the fifth edge E5 and extends from the end of the fifth edge E5 in the first horizontal direction D2. The seventh edge E7 is connected to an end of the sixth edge E6 and extends from the end of the sixth edge E6 in the second vertical direction −D1. The eighth edge E8 is connected to an end of the seventh edge E7 and extends from the end of the seventh edge E7 in the second diagonal direction −D3. The ninth edge E9 is connected to an end of the eighth edge E8 and extends from the end of the eighth edge E8 in the second vertical direction −D1. The tenth edge E10 is connected to an end of the ninth edge E9 and extends from the end of the ninth edge E9 in the first horizontal direction D2. The eleventh edge E11 is connected to an end of the tenth edge E10 and extends from the end of the tenth edge E10 in the first diagonal direction D3. The twelfth edge E12 is connected to an end of the eleventh edge E11 and extends from the end of the eleventh edge E11 in the first horizontal direction D2. The fifth edge E5, the eighth edge E8 and the eleventh edge E11 extend in the diagonal directions D3 and −D3 and are parallel to each other.

In this regard, the connection between the two edges means that the respective ends of the two edges facing each other are connected to each other. The two edges meet each other to form a vertex. “Connected” or “connection” may be used herein to refer to a physical connection between elements. When elements are described as “directly connected” or having a “direct connection,” no intervening elements may be present.

The protrusion P is composed of the fifth edge E5, the sixth edge E6, the seventh edge E7, and a portion of the eighth edge E8. The recess R is composed of the remainder of the eighth edge E8, the ninth edge E9, the tenth edge E10, and the eleventh edge E11. That is, the edge (the portion of the eighth edge E8) constituting the protrusion P and extending in the diagonal directions D3 and −D3 is connected to (e.g., with a continuous slope) the edge (the remainder of the eighth edge E8) constituting the recess R and extending in the diagonal directions D3 and −D3.

Generating the second target pattern TP2 from the first target pattern TP1 in S120 may include modifying the edge extending in the vertical directions D1 and −D1 and the edge extending in the horizontal directions D2 and D2 which constitute the inner corner CI and the outer corner O of the first target pattern TP1 into the edge extending in the vertical direction D1 and −D1, the edge extending in the horizontal directions D2 and −D2, and the edge extending in the diagonal direction D3 and −D3.

The thirteenth edge E13 to the fifteenth edge E15 are sequentially connected to each other. The fourteenth edge E14 extends in the first vertical direction D1. The thirteenth edge E13 extends from a first end of the fourteenth edge E14 in the second horizontal direction −D2. The fifteenth edge E15 extends from a second end of the fourteenth edge E14 in the first horizontal direction D2. Generating the second target pattern TP2 from the first target pattern TP1 in S120 may include modifying the bottom edge (EB of FIG. 3) of the first target pattern TP1 into the edge extending in the vertical directions D1 and −D1 and the edge extending in the horizontal directions D2 and −D2.

A shape of the recess R, a size of the recess R, a shape of the protrusion P, or a size of the protrusion P may vary depending on a distance (D of FIG. 3) between the inner corner CI and the outer corner CO of the first target pattern TP1 or a distance between an inner corner and an outer corner of the design pattern DP. At least one of lengths of the edges constituting the recess R and lengths of the edges constituting the protrusion P may vary depending on the distance (D of FIG. 3) between the inner corner CI and the outer corner CO of the first target pattern TP1 or the distance between the inner corner and the outer corner of the design pattern DP. At least one of lengths of the fifth to eleventh edges E5 to E11 may vary depending on the distance (D of FIG. 3) between the inner corner CI and the outer corner CO or the distance between the inner corner and the outer corner of the design pattern DP.

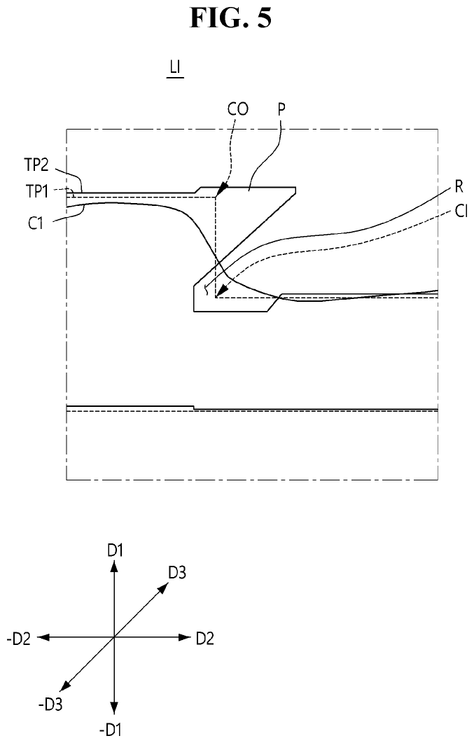

Referring to FIG. 1 and FIG. 5, optical proximity correction is performed on the second target pattern TP2 to extract a contour C1 of the second target pattern TP2 in S130. Mask data about the second target pattern TP2 may be input to an optical proximity correction model to perform simulation to extract the contour C1 of the second target pattern TP2.

Various basic data may be input to the optical proximity correction model. The basic data may include mask data about a fragment. Furthermore, the basic data may include numerical data such as a thickness, a refractive index, and a dielectric constant of PR (Photo Resist), and may include data of a source map about an illumination system shape. The basic data are not limited to the data as exemplified above. In one example, the mask data may include not only the fragment data, but also data such as a shape of patterns, a position of patterns, a measurement type (space or line measurement) of patterns, and basic measurement values.

The contour C1 of the second target pattern TP2 may correspond to a shape of a pattern formed on the wafer in an exposure process using a photo mask. That is, a shape of the contour C1 of the second target pattern TP2 may be transferred onto a substrate.

It is determined whether the contour C1 of the second target pattern TP2 satisfies a reference condition or whether the number of times the optical proximity correction is performed is a reference count in S140. The reference condition may include an error range between the contour C1 of the second target pattern TP2 and the first target pattern TP1, MRC (Mask Rule Check), and an allowable range of a corner rounding radius.

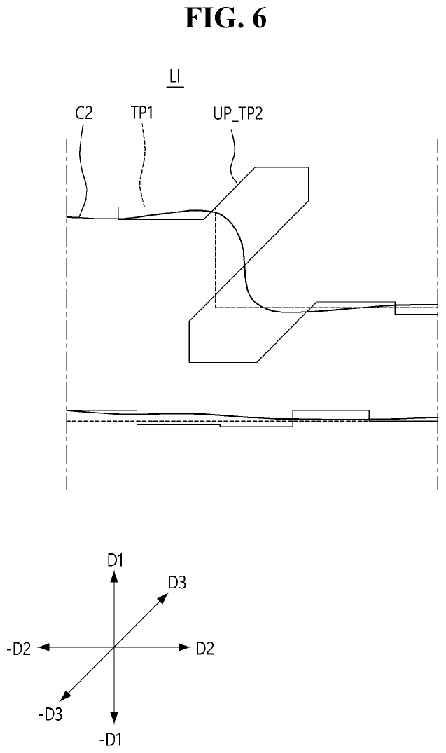

Referring to FIG. 1 and FIG. 6, when the contour C1 of the second target pattern TP2 does not satisfy the reference condition and the number of times the optical proximity correction is performed is not the reference count in S140, the second target pattern TP2 is updated using the first target pattern TP1 and the contour C1 of the second target pattern of TP2 in S150. A difference value between the first target pattern TP1 and the contour C1 of the second target pattern TP2 is calculated. The second target pattern TP2 may be updated using the difference value. Accordingly, updated second target pattern UP_TP2 may be generated.

Optical proximity correction is performed on the updated second target pattern UP_TP2 to extract a contour C2 of the updated second target pattern UP_TP2 in S130. Mask data about the updated second target pattern UP_TP2 may be input to the optical proximity model to perform simulation to the contour C2 of the updated second target pattern UP_TP2. It is determined whether the contour C2 of the updated second target pattern UP_TP2 satisfies the reference condition or whether the number of times the optical proximity correction is performed stratifies the reference count in S140.

The second target pattern TP2 may be repeatedly updated until the contour of the second target pattern TP2 satisfies the reference condition or the number of times the optical proximity correction is performed reaches the reference count.

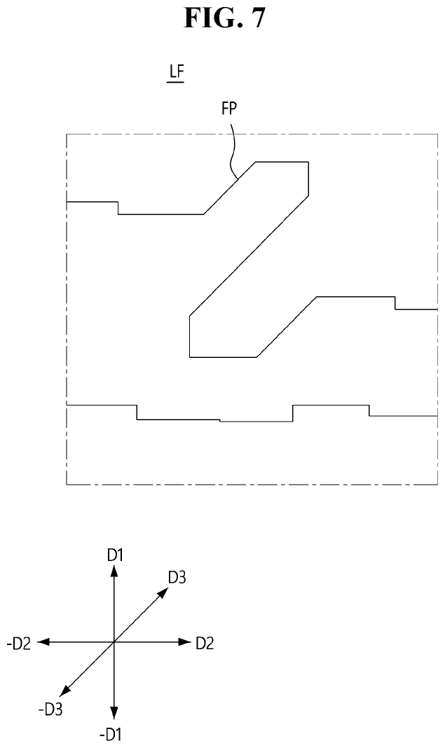

Referring to FIG. 1 and FIG. 7, when it is determined that the contour C1 of the second target pattern TP2 (or the contour C2 of one of the updated second target patterns UP_TP2) satisfies the reference condition or the number of times the optical proximity correction is performed is the reference count in S140, a final pattern FP is determined in S160. Accordingly, a final layout LF including the final pattern FP is generated. A mask may be fabricated using the final layout LF including the final pattern FP. For convenience of description, an example in which the final pattern FP is the updated second target pattern UP_TP2 in FIG. 6 is described.

The method for fabricating a mask according to some embodiments generates the final pattern FP using (e.g., by performing OPC on) the second target pattern TP2 or the updated second target pattern UP_TP2 including the edges extending in the vertical directions D1 and −D1, the edges extending in the horizontal directions D2 and −D2, and the edges extending in the diagonal directions D3 and −D3, that is, on a second target pattern that includes non-orthogonal edges. Therefore, an angle of the step portion of the final pattern FP, a length in the horizontal directions D2 and −D2 of the step portion of the final pattern FP, or the corner rounding radius may be improved, compared to a final pattern generated using a target pattern (e.g., the target pattern TP1) including edges extending in the vertical directions D1 and −D1 and edges extending in the horizontal directions D2 and −D2 only. The step portion of the final pattern FP (or the shape of the contour extracted therefrom) may be more approximate to (i.e., a closer approximation of) the step portion of the design pattern DP. That is, the step portion of the final pattern FP may be more perpendicular.

In addition, an amount of the mask data may be reduced and thus a manufacturing time of the mask pattern may be reduced, compared to a scheme of generating the final pattern using the target pattern including a curve.

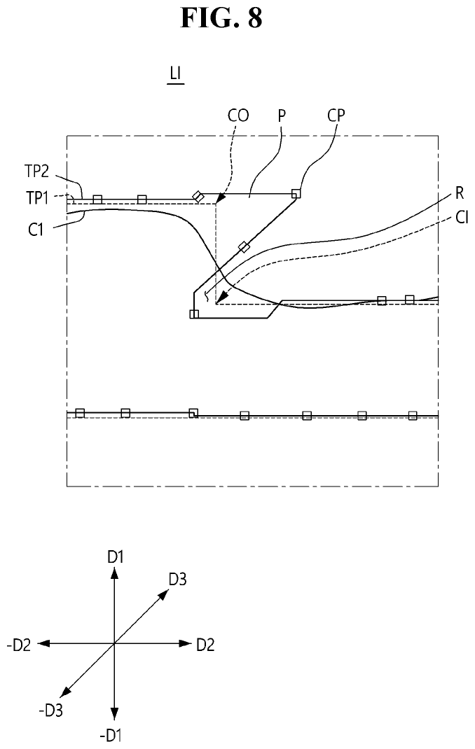

FIG. 8 is a flow chart for illustrating a method for fabricating a mask according to some embodiments.

Referring to FIGS. 1 and 8, performing the optical proximity correction on the second target pattern TP2 in S130 may include generating at least one control point CP on the second target pattern TP2. The control point CP may be positioned on an edge or a vertex of the second target pattern TP2. An outline of the second target pattern TP2 may be divided into a plurality of fragments via at least one control point CP. A fragment may be defined by neighboring control points CP.

Updating the second target pattern TP2 in S150 may include displacing one or more of the fragments. The fragment may be displaced in the vertical directions D1 and −D1, the horizontal directions D2 and −D2 or the diagonal directions D3 and −D3.

In some embodiments, updating the second target pattern TP2 in in S150 may include at least one of changing a position of the control point CP or changing the number of control points CP. After displacing the fragment of the second target pattern TP2 to generate the updated second target pattern, the position of the respective control points CP on the updated second target pattern may be changed and/or the number of control points CP may be changed. As the position of a respective control point CP is changed, a length of the fragment defined by the control points CP adjacent to each other may be changed. Subsequently, optical proximity correction may be performed on the updated second target pattern on which the changed control point(s) CP is disposed in S130.

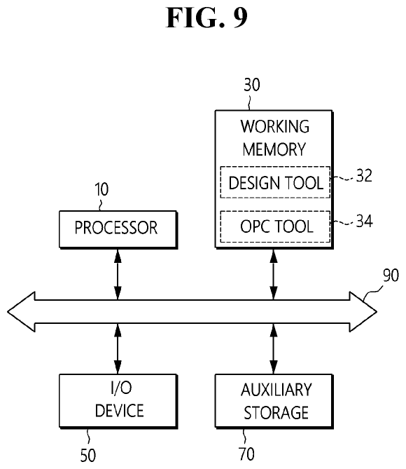

FIG. 9 is a block diagram showing a mask fabricating device according to some embodiments.

Referring to FIG. 9, the mask fabricating device includes a processor 10, a working memory 30, an input/output device 50, an auxiliary storage device 70, and a system interconnector 90.

For example, the mask fabricating device may be provided as a dedicated device for a method for fabricating a mask according to some embodiments or as a dedicated device for performing a semiconductor design including the same. For example, the mask fabricating device may have various design and verification simulation programs.

The processor 10 may execute software (an application program, an operating system, and a device driver) to be executed on the mask fabricating device. Although not shown, the processor 10 may execute the operating system OS loaded into the working memory 30. The processor 10 may execute various application programs to be driven based on the operating system. For example, the processor 10 may be a CPU (central processing unit), a microprocessor, AP (application processor), or any similar processing device.

The operating system or the application programs may be loaded into the working memory 30. Although not shown, in booting the mask fabricating device, an OS image stored in the auxiliary storage device 70 may be loaded into the working memory 30 according to a booting sequence. All input/output operations of the mask fabricating device may be supported by the operating system. Similarly, the application programs which may be selected by the user or may provide a basic service may be loaded into the working memory 30. In particular, a design tool 32 for the above-described semiconductor design, and/or an OPC tool 34 for the method for fabricating the mask according to the present disclosure may be loaded from the auxiliary storage device 70 into the working memory 30.

The design tool 32 may have a bias function that may change a shape and a position of specific layout patterns so as to be different from those defined by a design rule. Furthermore, the design tool 32 may perform design rule check (DRC) under the changed bias data condition. For example, the working memory 30 may be a volatile memory such as DRAM (dynamic random access memory), SRAM (static random access memory), or may be a non-volatile memory such as a flash memory, PRAM (phase change random access memory), RRAM (resistance random access memory), NFGM (nano floating gate memory), PoRAM (polymer random access memory), MRAM (magnetic random access memory), FRAM (ferroelectric random access memory), or the like.

The input/output device 50 may control user input and output from and into user interface devices. For example, the input/output device 50 may be equipped with input means such as a keyboard, a keypad, a mouse, a touch screen, etc., and may receive information from a designer. Using the input/output device 50, a user may receive information about a semiconductor area requiring adjusted operating characteristics, or data paths. Furthermore, the input/output device 50 may include output means such as a printer or a display to display a process and a process result of the design tool 32 and/or the OPC tool 34.

The auxiliary storage device 70 may be provided as a storage medium of the mask fabricating device. The auxiliary storage device 70 may store therein the application programs, the OS image, and various data. The auxiliary storage device 70 may be provided in a form of a mass storage device such as a memory card (MMC, eMMC, SD, MicroSD, etc.), HDD (hard disk drive), SSD (solid state drive), UFS (universal flash storage), or the like.

The system interconnector 90 may be a system bus for providing a network in the mask fabricating device. Via the system interconnector 90, the processor 10, the working memory 30, the input/output device 50, and the auxiliary storage device 70 may be electrically connected to each other and may exchange data with each other. However, a configuration of the system interconnector 90 is not limited to the above description, and may further include mediation means for efficient management.

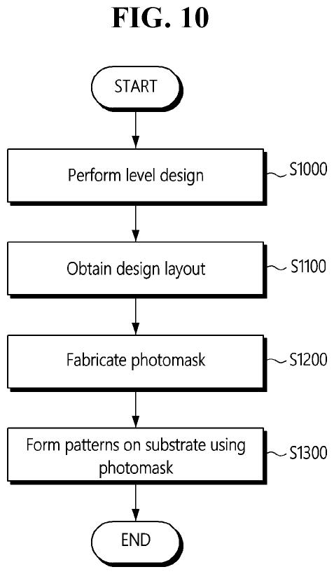

FIG. 10 is a flow chart illustrating a method for manufacturing a semiconductor device in accordance with some embodiments.

Referring to FIG. 10, a high-level design of the semiconductor device is performed in S1000.

The high-level design may mean describing an integrated circuit to be designed in a high-level language of a computer language. For example, the high-level language such as the C language may be used. Circuits designed in the high-level design may be expressed more specifically by register transfer level (RTL) coding or simulation. Furthermore, a code generated by the register transfer level coding may be converted into a netlist which in turn may be synthesized into a schematic circuit. The synthesized schematic circuit is verified by a simulation tool, and an adjustment process may be performed according to the verification result.

A design layout of a layer included in the semiconductor device is obtained in S1100. The design layout may be the initial layout LI as shown in FIG. 2.

In other words, a layout design for implementing a logically completed semiconductor device on a silicon substrate may be performed. For example, the layout design may be performed with referring to the schematic circuit synthesized in the high-level design or the netlist corresponding thereto. The layout design may include a routing procedure that places and connects various standard cells provided from a cell library to each other according to a prescribed design rule.

The cell library for the layout design may further contain information on an operation, a speed, and power consumption of the standard cell. A cell library for expressing a circuit of a specific gate level into a layout is defined in many layout design tools.

The layout may be a procedure for defining a shape or a size of a pattern constituting a transistor and a metal wire to be actually formed on a silicon substrate. For example, in order to actually form an inverter circuit on the silicon substrate, layout patterns such as PMOS, NMOS, N-WELL, gate electrodes, and metal wires to be disposed thereon may be properly placed. To this end, a suitable inverter may be searched for and selected from among inverters already defined in the cell library.

In addition, routing may be performed on the selected and placed standard cells. Specifically, routing of the selected and standard cells with higher level wires may be performed. The standard cells may be connected to each other according to the design in the routing procedure. Many of the processes in S1000 and S1100 as described above may be performed automatically or manually using the design tool 32 of FIG. 9. Furthermore, the placement and routing of the standard cells may be automatically performed using a separate Place & Routing tool.

After the routing, the layout may be verified to check whether a portion which violates the design rule is present. The verification may include DRC (Design Rule Check) which verifies whether the layout complies with the design rule, ERC (Electrical Rule Check) which verifies whether electrical disconnection occurs, and LVS (Layout vs Schematic) which verifies whether the layout matches the gate level netlist, etc.

The photo mask is fabricated in S1200. S1200 may be performed by the method for fabricating the mask as described above with reference to FIG. 1 to FIG. 8.

The optical proximity correction may be performed on the design layout to generate an updated design layout. The updated design layout may be the final layout LF including the final pattern FP as shown in FIG. 7.

Based on the design layout updated by the optical proximity correction performed on the target pattern having at least one non-orthogonal edge (such as a curved or diagonal edge), the photo mask is fabricated. In general, the photo mask may be fabricated in a scheme of depicting layout patterns using a chrome film applied on a glass substrate. However, the present disclosure is not limited thereto.

A pattern may be formed on a substrate using the photo mask in S1300. In this way, the semiconductor device may be manufactured.

In the manufacturing process of the semiconductor device using the photo mask, exposure and etch processes in various manners may be repeated. In these repeated processes, shapes of the patterns constructed during the layout design may be sequentially formed on the silicon substrate.

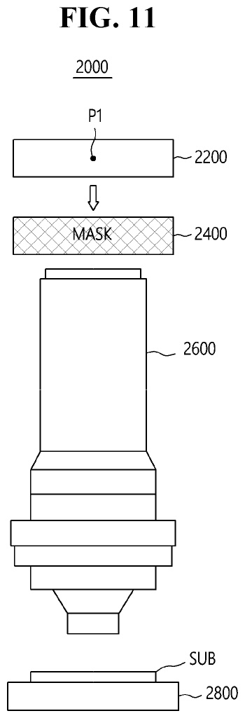

FIG. 11 is a block diagram illustrating a photolithography system for performing a method for manufacturing a semiconductor device according to some embodiments.

Referring to FIG. 11, a photolithography system 2000 may include a light source 2200, a photo mask 2400, a reduction projection device 2600 and a substrate stage 2800.

However, the photolithography system 2000 may further include components not as shown in FIG. 11. For example, the photolithography system 2000 may further include a sensor used to measure a height and a tilt of a surface of a substrate SUB.

The light source 2200 may emit light. The light emitted from the light source 2200 may be irradiated onto the photo mask 2400. For example, a lens may be provided between the light source 2200 and the photomask 2400 to adjust a light focus. The light source 2200 may include an ultraviolet light source (for example, a KrF light source with a wavelength of about 234 nm, an ArF light source with a wavelength of about 193 nm, and the like). The light source 2200 may include one point light source P1. However, the present disclosure is not limited thereto. In some embodiments, the light source 2200 may include a plurality of point light sources.

In order to print (implement) a designed layout on the substrate SUB, the photo mask 2400 may include image patterns. The image patterns may include a transparent area and an opaque area. The transparent area may be formed by etching a metal layer (for example, a chrome film) on the photo mask 2400. The light emitted from the light source 2200 may extend or pass through the transparent area. On the contrary, the opaque area may block the passage of light.

The reduction projection device 2600 may receive light which has passed through the transparent area of the photo mask 2400. The reduction projection device 2600 may match layout patterns to be printed on the substrate SUB with the image patterns of the photo mask 2400. The substrate stage 2800 may support the substrate SUB. For example, the substrate SUB may include a silicon wafer.

The reduction projection device 2600 may include an aperture. The aperture may be used to increase a depth of focus of the light emitted from the light source 2200. For example, the aperture may include a dipole aperture or a quadruple aperture. The reduction projection device 2600 may further include a lens to adjust the light focus.

The transparent area included in the image patterns of the photo mask 2400 may transmit the light emitted from the light source 2200 therethrough.

The light which has passed through the photo mask 2400 may be irradiated to the substrate SUB through the reduction projection device 2600. Thus, the patterns corresponding to the image patterns of the photo mask 2400 may be printed on the substrate SUB.

As integration of the semiconductor device increases, a distance between the image patterns of the photo mask 2400 becomes smaller and a width of the transparent area becomes smaller. Due to this “proximity”, light interference and diffraction occur, and thus a distorted layout different from a target layout may be printed on the substrate SUB. When the distorted layout is printed on the substrate SUB, the designed circuit may operate abnormally.

In order to reduce or prevent layout distortion, a resolution enhancement technique may be used. The optical proximity correction is an example of a resolution enhancement technique. According to the optical proximity correction, an amount of the distortion such as the interference and diffraction of light may be predicted. Furthermore, based on the predicted result, image patterns to be formed on the photo mask 2400 may be pre-biased. Thus, a desired layout may be printed on the substrate SUB.

In one embodiment, the optical proximity correction may be performed to adjust a layout of a single layer. In one example, in a semiconductor process, the semiconductor device may be implemented to include a plurality of layers. For example, the semiconductor device may include a stack of a plurality of metal layers to implement a specific circuit. Accordingly, the optical proximity correction may be independently performed on each of the plurality of layers.

Alternatively, when EUV (extreme ultraviolet) is used as the light source 2200, a configuration of the photolithography system 2000 may be changed.

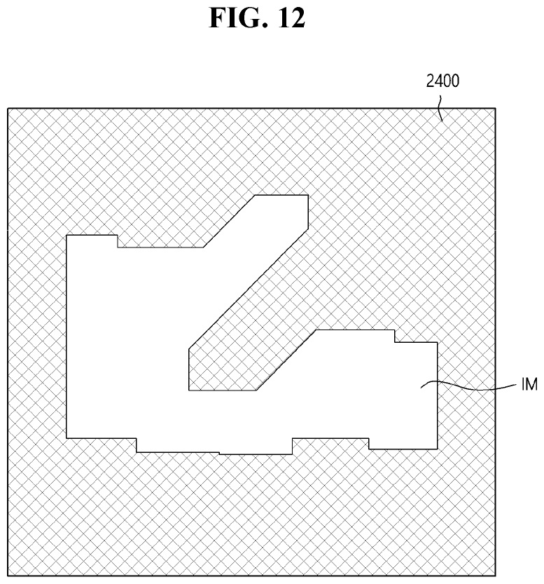

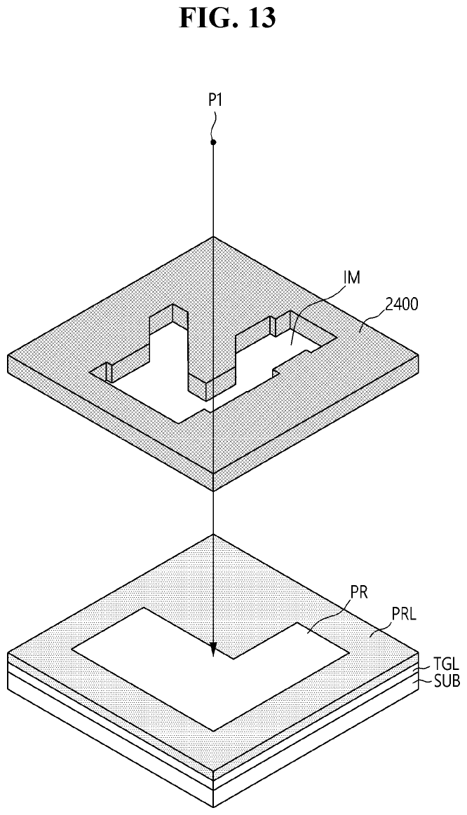

FIG. 12 is a diagram showing an example of a photo mask included in the photolithography system of FIG. 11. FIG. 13 is a diagram showing printing of a circuit pattern on a substrate using the photo mask of FIG. 12.

Referring to FIG. 12, a photo mask 2400 may include an image pattern IM corresponding to the final pattern FP of FIG. 7. The photo mask 2400 may include a transparent area and an opaque area. The opaque area may block light. In contrast, the transparent area may transmit therethrough the light emitted from the light source 2200 of FIG. 11. The light which has passed through the photo mask 2400 may be irradiated onto the substrate SUB of FIG. 11. For example, in a photolithography process using a negative photoresist, the image pattern IM may be a transparent area of the photomask 2400.

Referring to FIG. 13, a point light source P1 of the light source 2200 in FIG. 11 may emit light to the photo mask 2400. The emitted light may transmit or pass through the transparent area of the image pattern IM and be irradiated onto a photoresist layer PRL on the substrate SUB (exposure process). An area of the photoresist layer PRL onto which the light is irradiated may become the photoresist pattern PR. The photoresist pattern PR may be formed in the same shape and size as those of the contour C2 as described above in FIG. 6. FIG. 12 and FIG. 13 shows an example in which an inner corner and an outer corner of the image pattern IM are formed by the method for fabricating the mask according to some embodiments. However, a corner of an end of the image pattern IM having an inner angle of 90 degrees may also be manufactured by the method for fabricating the mask according to some embodiments.

Then, a developing process may be performed such that the photoresist pattern PR may remain and a remaining photoresist layer PRL may be removed. The remaining photoresist pattern PR may be used as an etch mask in patterning an etch target layer TGL on the substrate SUB. Thus, desired target patterns may be formed on the substrate SUB. As a result, the target patterns may be formed on each layer (in S1300 in FIG. 10). In this way, the semiconductor device may be manufactured.

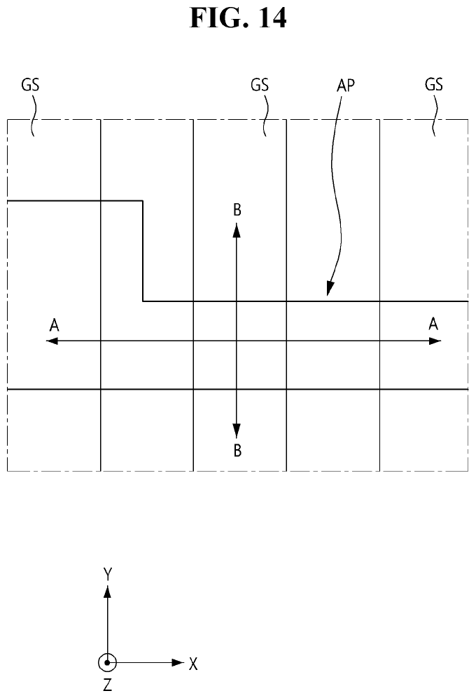

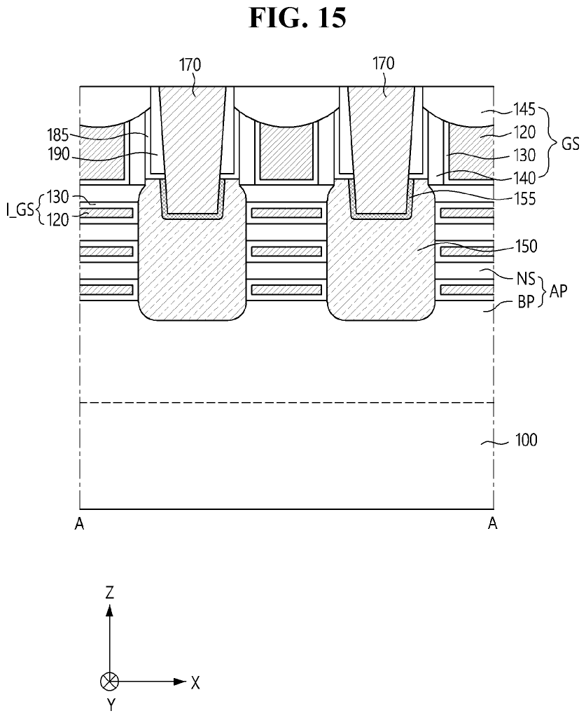

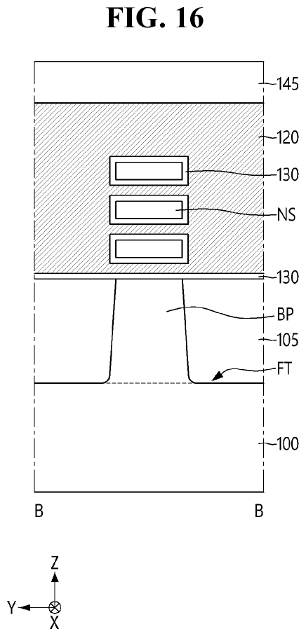

FIG. 14 to FIG. 16 are diagrams for illustrating a semiconductor device according to some embodiments. FIG. 15 is a cross-sectional view taken along A-A of FIG. 14. FIG. 16 is a cross-sectional view taken along B-B of FIG. 14.

Referring to FIG. 14 to FIG. 16, the semiconductor device according to some embodiments may include a substrate 100, an active pattern AP, a field insulating film 105, a gate structure GS, a source/drain pattern 150, a source/drain contact 170, and a source/drain etch stop film 185.

The substrate 100 may be made of a semiconductor material or may include a semiconductor material. The substrate 100 may be a silicon substrate or an SOI (silicon-on-insulator) substrate. Alternatively, the substrate 100 may include, for example, silicon germanium, SGOI (silicon germanium on insulator), indium antimonide, lead telluride compound, indium arsenide, indium phosphide, gallium arsenide, or gallium antimonide. However, the present disclosure is not limited thereto.

The active pattern AP may be disposed on the substrate 100. The active pattern AP may extend in an elongated manner in a first direction X. The active pattern AP may be a multi-channel active pattern. The active pattern AP may include a lower pattern BP and a plurality of sheet patterns NS. The lower pattern BP may protrude from the substrate 100. The lower pattern BP may extend in an elongated manner in the first direction X. A sidewall of the lower pattern BP may be defined by a fin trench FT. The active pattern AP may be formed by the method for manufacturing the semiconductor device according to some embodiments as described above.

The plurality of sheet patterns NS may be disposed on the lower pattern BP. The plurality of sheet patterns NS may be spaced apart from an upper surface of the lower pattern BP in a third direction Z. The sheet patterns NS may be spaced apart from each other in the third direction Z. Although it is shown that three sheet patterns NS are arranged in the third direction Z, this is only for convenience of illustration. However, the present disclosure is not limited thereto. A width in a second direction Y of the sheet pattern NS may increase or decrease in proportion to a width in a second direction Y of the lower pattern BP.

In this regard, the first direction X may intersect the second direction Y and the third direction Z. Furthermore, the second direction Y may intersect with the third direction Z. The third direction Z may be a thickness direction of the substrate 100.

The lower pattern BP may be formed by etching a portion of the substrate 100, or may include an epitaxial layer grown from the substrate 100. The lower pattern BP may include an elemental semiconductor material such as silicon or germanium. Furthermore, the lower pattern BP may include a compound semiconductor, for example, a group IV-IV compound semiconductor or a group III-V compound semiconductor. The sheet pattern NS may include one of the elemental semiconductor material such as silicon or germanium, the group IV-IV compound semiconductor or the group III-V compound semiconductor.

The field insulating film 105 is disposed on the substrate 100. The field insulating film 105 may be disposed on a sidewall of the lower pattern BP. The field insulating film 105 is not disposed on an upper surface of the lower pattern.

A plurality of gate structures GS may be disposed on the substrate 100. Each gate structure GS may extend in the second direction Y. The gate structures GS may be spaced apart from each other in the first direction X. The gate structures GS may be adjacent to each other in the first direction X. For example, the gate structure GS may be disposed on opposing sides in the first direction X of the source/drain pattern 150.

The gate structure GS may be disposed on the active pattern AP. The gate structure GS may intersect the active pattern AP. The gate structure GS may intersect the lower pattern BP. The gate structure GS may surround each sheet pattern NS. The term “surround” or “cover” as may be used herein may not require completely surrounding or covering the described elements or layers, but may, for example, refer to partially surrounding or covering the described elements or layers. The gate structure GS may include, for example, a gate electrode 120, a gate insulating film 130, a gate spacer 140, and a gate capping pattern 145.

The gate structure GS may include a plurality of inner gate structures I_GS respectively disposed between adjacent ones in the third direction Z of sheet patterns NS and between the lower pattern BP and the lowest sheet pattern NS. The inner gate structures I_GS may be respectively disposed between the upper surface of the lower pattern BP and the lower surface of the lowest sheet pattern NS, and between an upper surface of the sheet pattern NS and a lower surface of the sheet pattern NS facing each other in the third direction Z.

The gate electrode 120 may be disposed on the lower pattern BP. The gate electrode 120 may intersect with the lower pattern BP. The gate electrode 120 may surround the sheet pattern NS. A portion of the gate electrode 120 may be disposed between adjacent sheet patterns NS and between the lower pattern BP and the lowest sheet pattern NS. The gate electrode 120 may include at least one of a metal, a metal alloy, a conductive metal nitride, a metal silicide, a doped semiconductor material, a conductive metal oxide, or a conductive metal oxynitride.

The gate insulating film 130 may extend along the upper surface of the field insulating film 105 and the upper surface of the lower pattern BP. The gate insulating film 130 may surround the plurality of sheet patterns NS. The gate insulating film 130 may be disposed along a profile of the sheet pattern NS. The gate electrode 120 is disposed on the gate insulating film 130. The gate insulating film 130 is disposed between the gate electrode 120 and the sheet pattern NS. A portion of the gate insulating film 130 may be disposed between adjacent ones in the third direction Z of the sheet patterns NS and between the lower pattern BP and the lowest sheet pattern NS. The gate insulating film 130 may include silicon oxide, silicon oxynitride, silicon nitride, or a high-k material having a higher dielectric constant than that of silicon oxide. Although the gate insulating film 130 is illustrated as a single film, this is only for convenience of illustration, and the present disclosure is not limited thereto. The gate insulating film 130 may include a plurality of films.

The semiconductor device according to some embodiments may include an NC (Negative Capacitance) FET using a negative capacitor. For example, the gate insulating film 130 may include a ferroelectric material film having ferroelectric characteristics and a paraelectric material film having paraelectric characteristics.

A gate spacer 140 may be disposed on a sidewall of the gate electrode 120. The gate spacer 140 may not be disposed between the lower pattern BP and the lowest sheet pattern NS and between the sheet patterns NS adjacent to each other in the third direction Z. The gate spacer 140 may include, for example, at least one of SiN (silicon nitride), SiON (silicon oxynitride), SiO₂ (silicon oxide), SiOCN (silicon oxycarbonitride), SiBN (silicon boron nitride), SiOBN (silicon oxyboronitride), SiCO (silicon oxycarbide), or combinations thereof. Although the gate spacer 140 is shown as a single film, this is only for convenience of illustration, and the present disclosure is not limited thereto.

A gate capping pattern 145 may be disposed on the gate electrode 120. In contrast with what is shown, the gate capping pattern 145 may be disposed between the gate spacers 140. The gate capping pattern 145 may include, for example, at least one of silicon nitride, silicon oxynitride, silicon carbonitride, silicon oxycarbonitride, or combinations thereof.

The source/drain pattern 150 may be disposed on the active pattern AP. The source/drain pattern 150 may be disposed on the lower pattern BP. The source/drain pattern 150 may be disposed on a side surface of the gate structure GS. The source/drain pattern 150 may be included in a source/drain of a transistor using the sheet pattern NS as a channel area. The source/drain pattern 150 may include an epitaxial pattern. The source/drain pattern 150 may include a semiconductor material.

The source/drain etch stop film 185 may extend along an outer wall of the gate spacer 140 and a profile of the source/drain pattern 150. Although not shown, the source/drain etch stop film 185 may be disposed on the upper surface of the field insulating film 105. The source/drain etch stop film 185 may include, for example, at least one of silicon nitride, silicon oxynitride, silicon oxycarbonitride, silicon boron nitride, silicon oxyboronitride, silicon oxycarbide, or combinations thereof.

An interlayer insulating film 190 may be disposed on the source/drain etch stop film 185. The interlayer insulating film 190 may be disposed on the source/drain pattern 150. The interlayer insulating film 190 may not cover an upper surface of the gate capping pattern 145. For example, an upper surface of the interlayer insulating film 190 may be coplanar with an upper surface of the gate capping pattern 145. The interlayer insulating film 190 may include, for example, at least one of silicon oxide, silicon nitride, silicon oxynitride, or a low dielectric constant material.

The source/drain contact 170 is disposed on the source/drain pattern 150. The source/drain contact 170 is connected to the source/drain pattern 150. The source/drain contact 170 may extend through the interlayer insulating film 190 and the source/drain etch stop film 185 so as to be connected to the source/drain pattern 150. The source/drain contact 170 is shown as a single film. However, this is only for convenience of illustration, and the present disclosure is not limited thereto. The source/drain contact 170 may include at least one of, for example, a metal, a metal alloy, a conductive metal nitride, a conductive metal carbide, a conductive metal oxide, a conductive metal carbonitride, or a two-dimensional (2D) material.

A metal silicide layer 155 may be further disposed between the source/drain contact 170 and the source/drain pattern 150.

Referring to FIG. 14, the active pattern AP may include portions having different widths in the second direction Y. Accordingly, the active pattern AP may include a step portion. In this regard, as a length in the first direction X of the step portion of the active pattern AP increases or an inclination angle of the step portion of the active pattern AP with respect to the second direction Y increases, a distance between the active pattern AP and the gate structure GS becomes smaller. Accordingly, a defect in the semiconductor device may occur.

However, the active pattern AP may be formed using the mask formed by the method for fabricating the mask according to some embodiments. Accordingly, the active pattern AP may have a shape more approximate to that of the design pattern. That is, the step portion of the active pattern AP may be more perpendicular. As a result, the distance between the active pattern AP and the gate structure GS may be increased, thereby reducing or preventing defects in the semiconductor device.

Although embodiments of the present disclosure have been described with reference to the accompanying drawings, the present disclosure is not limited to the above embodiments, but may be implemented in various different forms. A person skilled in the art may appreciate that the present disclosure may be practiced in other tangible forms or practical applications without changing the scope of the present disclosure. Therefore, it should be appreciated that the embodiments as described above is not restrictive but illustrative in all respects.

What is claimed is:

1. A method for fabricating a mask for a manufacturing a semiconductor device, the method comprising:
generating a first target pattern including a step portion having an inner corner and an outer corner that are spaced apart in a vertical direction;
generating a second target pattern from the first target pattern;
performing optical proximity correction on the second target pattern to generate a final pattern; and
fabricating the mask using the final pattern,
wherein generating the second target pattern comprises:
forming a recess extending inwardly and in a diagonal direction relative to the inner corner of the step portion; and
forming a protrusion protruding outwardly and in the diagonal direction relative to the outer corner of the step portion.

2. The method of claim 1, wherein an angle defined between the vertical direction and the diagonal direction is about 45 degrees.

3. The method of claim 1, wherein at least one edge of the recess or at least one edge of the protrusion comprises a length that varies based on a distance between the inner corner and the outer corner.

4. The method of claim 1, wherein the recess and the protrusion are connected to each other and comprise a common edge having a continuous slope.

5. The method of claim 1, wherein the recess comprises:
a first edge extending in the diagonal direction;
a second edge extending in the diagonal direction and parallel to the first edge;
a third edge connected to the first edge and extending in the vertical direction; and
a fourth edge connected to the second edge and the third edge and extending in a horizontal direction.

6. The method of claim 1, wherein the protrusion comprises:
a first edge extending in the diagonal direction;
a second edge extending in the diagonal direction and parallel to the first edge;
a third edge connected to the first edge and extending in a horizontal direction; and
a fourth edge connected to the second edge and the third edge and extending in the vertical direction.

7. The method of claim 1, wherein the first target pattern comprises:
at least one first edge extending in a horizontal direction, and at least one second edge extending in the vertical direction,
wherein the second target pattern has:
at least one third edge extending in the horizontal direction;
at least one fourth edge extending in the vertical direction; and
at least one fifth edge extending in the diagonal direction.

8. The method of claim 1, further comprising:
determining whether a contour of the second target pattern obtained by performing the optical proximity correction on the second target pattern satisfies a reference condition or whether a number of times the optical proximity correction is performed reaches a reference count; and
generating the final pattern responsive to the determining.

9. A method for fabricating a mask for a manufacturing a semiconductor device, the method comprising:
generating a first target pattern;
generating a second target pattern from the first target pattern;
performing optical proximity correction on the second target pattern to generate a final pattern; and
fabricating the mask using the final pattern,
wherein the first target pattern comprises:
a first edge extending in a first vertical direction;
a second edge connected to one end of the first edge and extending in a first horizontal direction; and
a third edge connected to another end of the first edge and extending in a second horizontal direction opposite to the first horizontal direction,
wherein the second target pattern comprises:
a fourth edge extending in a first diagonal direction;
a fifth edge connected to the fourth edge and extending in the first horizontal direction;
a sixth edge connected to the fifth edge and extending in a second vertical direction opposite to the first vertical direction;
a seventh edge connected to the sixth edge and extending in a second diagonal direction opposite to the first diagonal direction;
an eighth edge connected to the seventh edge and extending in the second vertical direction;
a ninth edge connected to the eighth edge and extending in the first horizontal direction; and
a tenth edge connected to the ninth edge and extending in the first diagonal direction.

10. The method of claim 9, wherein an angle defined between the first vertical direction and the first diagonal direction is about 45 degrees.

11. The method of claim 9, wherein at least one of the fourth, fifth, sixth, seventh, eighth, ninth, or tenth edges of the second target pattern comprises a length that varies based on a length of the first edge of the first target pattern.

12. The method of claim 9, wherein a vertex at which the fifth edge and the sixth edge meet each other is positioned outside of a boundary defined by the first, second, and third edges of the first target pattern, and
wherein a vertex at which the eighth edge and the ninth edge meet each other is positioned within the boundary defined by the first, second, and third edges of the first target pattern.

13. The method of claim 9, wherein the second target pattern further comprises:
an eleventh edge extending in the first horizontal direction and connected to the fourth edge; and
a twelfth edge extending in the first horizontal direction and connected to the tenth edge.

14. A method for manufacturing a semiconductor device, the method comprising:
fabricating a mask; and
performing a photo process on a substrate using the mask to manufacture the semiconductor device,
wherein fabricating the mask comprises:
generating a first target pattern, wherein the first target pattern includes a step portion having an inner corner and an outer corner that are spaced apart in a vertical direction;
generating a second target pattern from the first target pattern;
performing optical proximity correction on the second target pattern;
determining a final pattern based on the optical proximity correction; and
fabricating the mask using the final pattern,
wherein generating the second target pattern comprises:
forming a recess extending inwardly and in a diagonal direction relative to the inner corner of the step portion; and
forming a protrusion protruding outwardly and in the diagonal direction relative to the outer corner of the step portion.

15. The method of claim 14, wherein performing the optical proximity correction on the second target pattern comprises extracting a contour of the second target pattern, and
wherein determining the final pattern based on the optical proximity correction result comprises:
upon determination that the contour of the second target pattern satisfies a reference condition or that a number of times the optical proximity correction is performed reaches a reference count, determining the second target pattern as the final pattern; or
upon determination that the contour of the second target pattern does not satisfy the reference condition or that the number of times the optical proximity correction is performed does not reach the reference count, generating an updated second target pattern using the first target pattern and the contour of the second target pattern, performing further optical proximity correction on the updated second target pattern to extract a contour of the updated second target pattern, and upon determination that the contour of the updated second target pattern satisfies the reference condition or that a number of times the further optical proximity correction is performed reaches the reference count, determining the updated second target pattern as the final pattern.

16. The method of claim 15, wherein performing the optical proximity correction on the second target pattern includes generating at least one control point on the second target pattern, and
wherein generating the updated second target pattern includes at least one of changing a position of the at least one control point or changing a number of the at least one control point.

17. The method of claim 14, wherein the first target pattern comprises:
at least one first edge extending in a horizontal direction; and
at least one second edge extending in a vertical direction,
wherein the second target pattern comprises:
at least one third edge extending in the horizontal direction;
at least one fourth edge extending in the vertical direction; and
at least one fifth edge extending in a diagonal direction.

18. The method of claim 14, wherein an angle defined between the vertical direction and the diagonal direction is about 45 degrees.

19. The method of claim 14, wherein at least one edge of the recess or at least one edge of the protrusion comprises a length that varies based on a distance between the inner corner and the outer corner.

20. The method of claim 14, wherein the recess and the protrusion are connected to each other and comprise a common edge having a continuous slope.
